(19) United States
(12) Patent Application Publication
(10) Pub. No.: US 2011/0021025 A1
(43) Pub. Date: Jan. 27, 2011

(54) METHOD FOR PRODUCING LASER-MARKED SEMICONDUCTOR WAFER

(75) Inventors: Tomohiro Hashii, Minato-ku (JP); Kenji Aoki, Minato-ku (JP)

Correspondence Address: CHRISTENSEN, O'CONNOR, JOHNSON, KINDNESS, PLLC, 1420 FIFTH AVENUE, SUITE 2800, SEATTLE, WA, 98101-2347, US

(73) Assignee: SUMCO CORPORATION, Tokyo (JP)

(21) Appl. No.: 12/841,015

(22) Filed: Jul. 21, 2010

(30) Foreign Application Priority Data
Jul. 24, 2009 (JP) 2009-172717

(51) Int. Cl. H01L 21/302

(52) U.S. Cl. 438/691; 257/E21.214

(57) ABSTRACT

A laser-marked semiconductor wafer having a good flatness in the vicinity of laser mark-printed sites is produced by a method comprising a slicing step; a planarization step; a laser mark printing step; a grinding step; an etching step; and a polishing step.

### BACKGROUND

1. Field of the Invention

This invention relates to a method for producing a laser-marked semiconductor wafer wherein laser marks are formed in the vicinity of a notch on the wafer.

2. Description of the Related Art

As an example of the method for producing a laser-marked semiconductor wafer by forming laser marks in the vicinity of a notch on the wafer, there is known a production method wherein a slicing step of cutting out a disc-shaped wafer from a single crystal ingot and a lapping step of making uniform a thickness of the thus obtained disc-shaped wafer are conducted, and thereafter laser marking is applied to the surface of the wafer in a state that a lapping powder layer remains on the surface of the wafer, and then the wafer is subjected to a cleaning with an alkaline aqueous solution for removing splattered particles generated by the laser marking together with the lapping powder layer (e.g., see JP-A-2006-186173).

In the above conventional method, the splattered particles and the like to be removed, which are generated by the laser marking, are removed together with the lapping powder layer by cleaning with the alkaline aqueous solution. After the cleaning with the alkaline aqueous solution, polishing is carried out with a polishing solution containing abrasive grains to prepare a final semiconductor wafer. In this case, a semiconductor wafer having a good flatness even at laser-marked places can be obtained since no influence of the splattered particles generated by the laser marking is confirmed at all.

However, in further inspections on the method for producing a semiconductor wafer, it has been found that when polishing with a polishing solution containing no abrasive grain is conducted instead of the polishing with the polishing solution containing abrasive grains after the laser marking and cleaning with the alkaline aqueous solution, there is caused a problem of retaining the splattered particles and the like generated by the laser marking, which is out of question in the polishing with the polishing solution containing abrasive grains. In particular, there are caused influences based on minute and uneven elevated portions formed in the periphery of the print site by the laser marking, welding of Si splattered particles generated during the printing and the like.

### SUMMARY

It is, therefore, an object of the invention to advantageously solve the above problems and to provide a method for producing a laser-marked semiconductor wafer in which the deterioration of flatness in the vicinity of print sites can be prevented by eradicating influences based on minute and uneven elevated portions formed in the periphery of the print site by the laser marking, welding of Si spattered particles generated during the printing and the like.

The inventors have made various studies about the method for producing a laser-marked semiconductor wafer in order to solve the above problems. As a result, it has been found that the influences based on the minute and uneven elevated portions formed in the periphery of the print site by the laser marking, welding of Si splattered particles generated during the printing and the like cannot be removed only by the conventional cleaning with the alkaline aqueous solution after the laser marking. Moreover, it has been discovered the above problems could be solved by mechanical polishing with abrasive grains as in the conventional polishing with the polishing solution containing abrasive grains, but when the polishing with a polishing solution containing no abrasive grain is used, the influences based on the minute and uneven elevated portions formed in the periphery of the print site by the laser marking, welding of Si splattered particles generated during the printing and the like, which can not be removed completely by the cleaning with the alkaline aqueous solution, remains as they are.

The invention is based on the above knowledge and the summary and construction thereof are as follows.

(1) A method for producing a laser-marked semiconductor wafer which comprises a slicing step of cutting out a disc-shaped wafer from a single crystal ingot; a planarization step of making a thickness of the cut disc-shaped wafer uniform; a laser mark printing step of printing laser marks for wafer identification on the surface of the planarized wafer through laser; a grinding step of grinding at least the laser-marked surface of the laser-marked wafer by a predetermined thickness considering (1) the removal of uneven elevated portions formed in the periphery of the laser mark-printed site and (2) the preservation of a depth of the laser mark-printed site; an etching step of etching at least the laser mark-printed site of the wafer after the grinding; and a polishing step of polishing the wafer surface after the etching with a polishing solution containing no abrasive grain.

(2) A method for producing a laser-marked semiconductor wafer according to the item (1), wherein the predetermined thickness to be ground in the grinding step is 5 to 50 μm.

(3) A method for producing a laser-marked semiconductor wafer according to the item (1), wherein the planarization step is conducted by lapping both surfaces of the cut wafer.

(4) A method for producing a laser-marked semiconductor wafer according to the item (1), wherein the laser marks printed in the laser mark printing step are formed on the surface of the wafer in the vicinity of a notch.

(5) A method for producing a laser-marked semiconductor wafer according to the item (1), wherein the etching step is conducted with an alkaline solution.

(6) A method for producing a laser-marked semiconductor wafer according to the item (1), wherein the polishing step comprises a double-sided first polishing step of simultaneously first-polishing both surfaces of the wafer with a polishing solution containing no abrasive grain and a one-side finish polishing step of finish-polishing at least one surface of both the first-polished surfaces of the wafer, one surface at a time, with a polishing solution containing no abrasive grain.

According to the method for producing a laser-marked semiconductor wafer according to the invention, the grinding step of grinding at least the laser-marked surface of the laser-marked wafer by a predetermined thickness considering (1) the removal of uneven elevated portions formed in the periphery of the laser mark-printed site and (2) the preservation of a depth of the laser mark-printed site is conducted after the laser mark printing step, whereby even if polishing with a polishing solution containing no abrasive grain is conducted in the subsequent polishing step, influences based on the minute and uneven elevated portions formed in the periphery of the print site by the laser marking, welding of Si splattered particles generated during the printing and the like can be eradicated to prevent the deterioration of flatness in the vicinity of the print sites.

### DESCRIPTION OF THE DRAWINGS

The patent or application file contains at least one drawing executed in color. Copies of this patent or patent application publication with color drawings will be provided by the Office upon request and payment of the necessary fee.

The invention will be described with reference to the accompanying drawings, wherein:

FIG. 1 is a view illustrating an example of a laser-marked semiconductor wafer produced in the method for producing a laser-marked semiconductor wafer according to the invention;

FIG. 2 is a flow chart showing an example of each production step in the method for producing a laser-marked semiconductor wafer according to the invention;

FIG. 3 is a view illustrating an example of a laser mark formed by the laser mark printing step;

FIGS. 4 (a) to (c) are optical microphotographs each showing a state of a laser mark at each step in a semiconductor wafer of Invention Example, respectively; and

FIGS. 5 (a) to (c) are optical microphotographs each showing a state of a laser mark at each step in a semiconductor wafer of Reference Example, respectively.

### DETAILED DESCRIPTION

Next, the method for producing a laser-marked semiconductor wafer according to the invention will be described in detail with reference to the drawings.

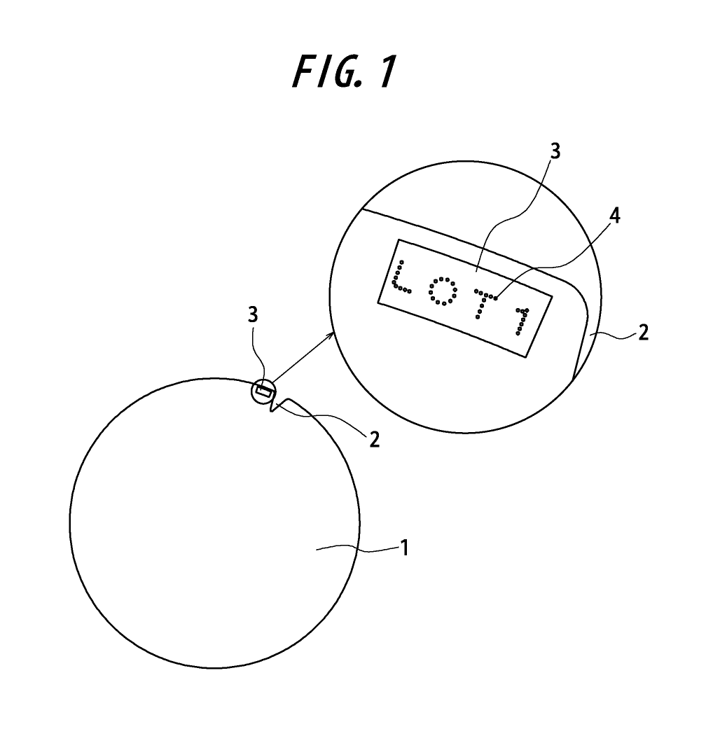

FIG. 1 is a view illustrating an example of a laser-marked semiconductor wafer produced in the method for producing a laser-marked semiconductor wafer according to the invention. In the example of FIG. 1, a notch 2 for matching a direction of a wafer 1 in each production step is formed in a part of an outer periphery of the wafer 1. In order to identify the wafer 1, a laser mark-printed portion 3 is provided in the vicinity of the notch 2. The size of the laser mark-printed portion 3 is about 2 mm×20 mm as an example. As seen from an enlarged portion shown in this figure, the laser mark-printed portion 3 has a character, bar-code or the like printed as an assembly of plural laser marks (dots) 4 shot by a laser. The character, bar-code or the like printed in the laser mark-printed portion 3 is read at each step and used for identifying quality and the like of the wafer 1. Thus, the wafer 1 provided with the laser mark-printed portion 3 is considered as a laser-marked semiconductor wafer produced in the invention.

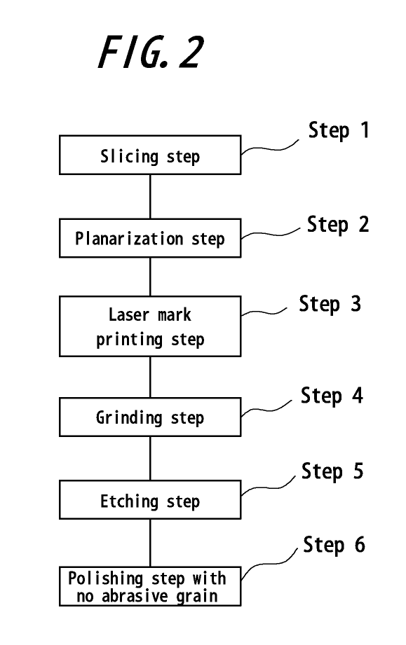

FIG. 2 is a flow chart showing an example of each production step in the method for producing a laser-marked semiconductor wafer according to the invention. As described in accordance with the flow chart of FIG. 2, the method for producing a laser-marked semiconductor wafer according to the invention comprises a slicing step (step 1) of cutting out a disc-shaped wafer from a single crystal ingot; a planarization step (step 2) of making a thickness of the cut disc-shaped wafer uniform; a laser mark printing step (step 3) of printing laser marks for wafer identification on the surface of the planarized wafer through laser; a grinding step (step 4) of grinding at least the laser-marked surface of the laser-marked wafer by a predetermined thickness considering (1) the removal of uneven elevated portions formed in the periphery of the laser mark-printed site and (2) the preservation of a depth of the laser mark-printed site; an etching step (step 5) of etching at least the laser mark-printed sites of the wafer after the grinding; and a polishing step (step 6) of polishing the wafer surface after the etching with a polishing solution containing no abrasive grain.

Then, each step of the method for producing a laser-marked semiconductor wafer according to the invention in the flow chart of FIG. 2 will be described.

<Slicing Step>
The slicing step (step 1) of the invention is a step wherein a disc-shaped wafer is cut out by contacting a wire saw with a crystalline ingot while supplying a grinding solution, or by cutting a crystalline ingot with an inner diameter blade. In order to reduce the processing load in the subsequent planarization step (step 2), the crystalline ingot is typically an ingot of silicon single crystal but not particularly limited, and may be an ingot of polycrystalline silicon for solar cells.

<Planarization Step>
The planarization step (step 2) of the invention is a step wherein the surface of the wafer cut out in the slicing step is subjected to lapping for improving the flatness of the wafer but also approximating the wafer to a final thickness. In case of conducting the lapping, free abrasive grains within a range of #1000 to 1500 are preferably used for the lapping. Instead of the lapping may be adopted a technique wherein high-accuracy planarization of the wafer is conducted by a grinding step using a flat-surface grinding machine or a double-sided simultaneous flat-surface grinding machine to reduce variation or undulation in the thickness of the wafer. Although the lapping may be conducted to both surfaces or one surface, the lapping of both surfaces is preferable in terms of the flatness.

<Laser Mark Printing Step>
The laser mark printing step (step 3) of the invention is a step wherein laser marks for wafer identification are printed on the surface of the wafer after the planarization in the planarization step through laser. The printing position is on an outer peripheral portion of the wafer surface and in the vicinity of the notch. For example, an Nd:YAG laser is irradiated onto the laser mark-printing sites of the wafer surface at an output power of 10 to 100 W plural times to form a predetermined character or bar-code by laser marking. The depth of the laser mark is about 5 to 100 μm.

<Grinding Step>
The grinding step (step 4) of the invention is a step of grinding at least the laser-marked surface of the laser-marked wafer by a predetermined thickness. An example of the grinding method is as follows. The grinding method may be any method capable of grinding the wafer surface. For example, there can be adopted an in-feed type flat-surface grinding wherein the wafer is placed on a chuck table and contacted with a cup-shaped grindstone while rotating the chuck table at a high speed, or the like.

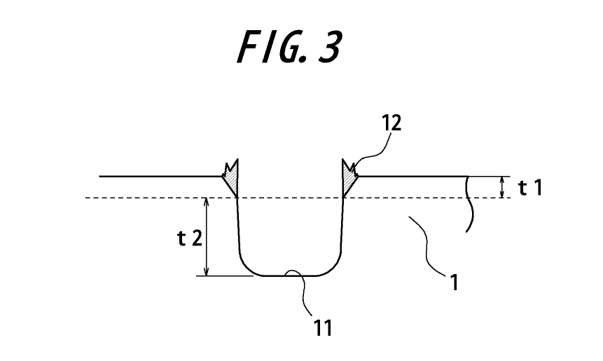

In the grinding step of the invention, a thickness of the wafer to be removed by grinding is important. FIG. 3 is a view illustrating an example of a laser mark formed in the laser mark printing step. In the example of FIG. 3, a laser mark 11 is formed by laser irradiation wherein an affected portion shown by a shaded area is formed at the periphery of the laser mark-printed site by heat of the laser. As a result, an uneven elevated portion 12 is formed in the periphery of the laser mark-printed site by the affected portion resulted from heat of the laser. Therefore, it is preferable to remove a thickness t1 of the uneven elevated portion 12 resulted from the affected portion by the grinding. On the other hand, if a depth t2 of the laser mark after the removal of the thickness t1 by grinding is too shallow, it becomes impossible to read the content printed by laser marking for wafer identification. In the invention, therefore, the grinding allowance is a predetermined thickness t1 considering (1) the removal of the uneven elevated portion 12 formed in the periphery of the laser mark-printed site and (2) the preservation of a depth of the laser mark-printed site. Concretely, the thickness t1 is preferable to be 5 to 50 μm.

<Etching Step>
The etching step (step 5) of the invention is a step of etching at least the laser mark-printed site of the wafer after the grinding. As an example of the etching can be used a method wherein the wafer after the laser marking and grinding steps is immersed and held in an etching solution filled in an etching tank and etched while rotating the wafer. As the etching solution, it is preferable to use an alkaline etching solution, and further preferable to use an etching solution being an aqueous solution of sodium hydroxide or potassium hydroxide. In the etching step can be removed, if any, the uneven elevated portion or splattered particles retained without removing in the grinding step.

<Polishing Step with No Abrasive Grain>

The polishing step with no abrasive grain (step 6) of the invention is a step wherein the surface of the etched wafer is polished with a polishing solution containing no abrasive grain. The important point in the polishing step with no abrasive grain of the invention is that although the same polishing method as the conventional polishing method is used, the conventional polishing using a polishing apparatus with a polishing solution containing abrasive grains is changed into a polishing using a polishing apparatus with a polishing solution containing no abrasive grain in the invention.

In the polishing step with no abrasive grain of the invention is generally conducted a multistage polishing comprising the first polishing and the second polishing (finish polishing). Here, the first polishing is preferable to be a double-sided first polishing step of simultaneously first-polishing both surfaces of the wafer with a polishing solution containing no abrasive grain. In the first polishing, the wafer is held in the apparatus and upper and lower platens each lined with a polishing cloth are pushed onto both the front and back surfaces of the wafer to rotate the wafer on its axis and also around while supplying a polishing solution containing no abrasive grain. Thereby, the front and back surfaces of the wafer are polished simultaneously. The second polishing is preferable to be a one-side finish polishing step of finish-polishing at least one surface of both the first-polished surfaces of the wafer, one surface at a time. The second polishing includes polishing of only one surface and/or polishing of both surfaces. When both surfaces are polished, first one surface is polished and then the other surface is polished.

According to the above-mentioned method for producing a laser-marked semiconductor wafer according to the invention, the grinding step (step 4) of finish-grinding at least one surface or both surfaces including the laser mark-printed portions with a high accuracy and a low strain is conducted after the laser mark printing step (step 3) of printing marks by laser shooting in the vicinity of the notch for identifying the wafer and before the etching step (step 5), whereby it is made possible to grind minute and uneven elevated portions at the interface between the wafer surface and the laser mark-printed site, and welding of Si splattered particles. Therefore, even if the subsequent polishing step (step 6) containing no abrasive grain is conducted, it is possible to prevent the deterioration of the flatness due to the laser marking in a final semiconductor wafer.

Hereinafter, actual examples will be described. It should be noted that the invention is not limited to the following examples.

### Example 1

A semiconductor wafer of Invention Example is prepared according to the flow chart of FIG. 2 by sequentially conducting a slicing step (step 1) of cutting out a disc-shaped wafer from a single crystal ingot; a planarization step (step 2) of making a thickness of the cut disc-shaped wafer uniform; a laser mark printing step (step 3) of printing laser marks for wafer identification on the surface of the planarized wafer through laser; a grinding step (step 4) of grinding at least the laser-marked surface of the laser-marked wafer by a predetermined thickness considering (1) the removal of uneven elevated portions formed in the periphery of the laser mark-printed site and (2) the preservation of a depth of the laser mark-printed site; an etching step (step 5) of etching at least the laser mark-printed sites of the wafer after the grinding; and a polishing step (step 6) of polishing the wafer surface after the etching with a polishing solution containing no abrasive grain.

Then, a state of a laser mark at each step is observed by using an optical microscope after the ends of the laser making printing step (step 3), the grinding step (step 4) and the polishing step with no abrasive grain polishing step (step 6), respectively. Moreover, the flatness of the finally obtained semiconductor wafer is measured by using a capacitive sensor for thickness measurement.

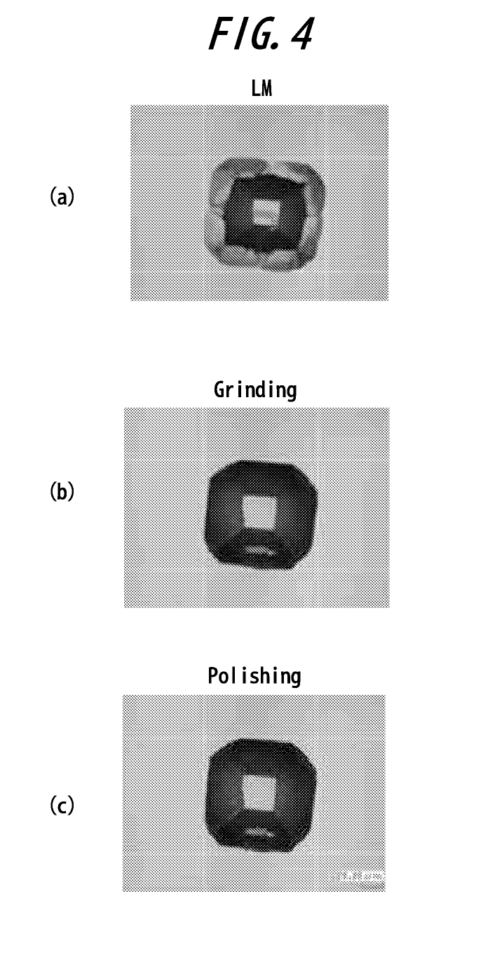

FIGS. 4 (a) to (c) show results on the state of the laser mark observed by the optical microscope in the semiconductor wafer of Invention Example during the production process, respectively, wherein (a) shows a state of the laser mark after the end of the laser mark printing step (step 3), and (b) shows a state of the laser mark after the end of the grinding step (step 4), and (c) shows a state of the laser mark after the polishing step with no abrasive grain (step 6). As seen from the results of FIGS. 4 (a) to (c), uneven elevated portions observed in the periphery of the laser mark-printed site after the end of the laser mark printing step (pale and transparent part in the outer periphery portion) are completely ground after the grinding step, the state of which is maintained even after the polishing step with no abrasive grain. Also, the flatness of the finally obtained semiconductor wafer is less than 0.5 μm and is good.

### Reference Example 1

A semiconductor wafer of Reference Example is prepared in accordance with a flow chart of removing the grinding step (step 4) from the flow chart of the invention by sequentially conducting a slicing step (step 1) of cutting out a disc-shaped wafer from a single crystal ingot; a planarization step (step 2) of making a thickness of the cut disc-shaped wafer uniform; a laser mark printing step (step 3) of printing laser marks for wafer identification on the surface of the planarized wafer through laser; an etching step (step 5) of etching at least the laser mark-printed sites of the wafer after the grinding; and a polishing step (step 6) of polishing the wafer surface after the etching with a polishing solution containing no abrasive grain.

Then, a state of a laser mark at each step is observed by using an optical microscope after the ends of the laser making printing step (step 3), the etching step (step 5) and the polishing step with no abrasive grain polishing step (step 6), respectively. Moreover, the flatness of the finally obtained semiconductor wafer is measured by using a capacitive sensor for thickness measurement.

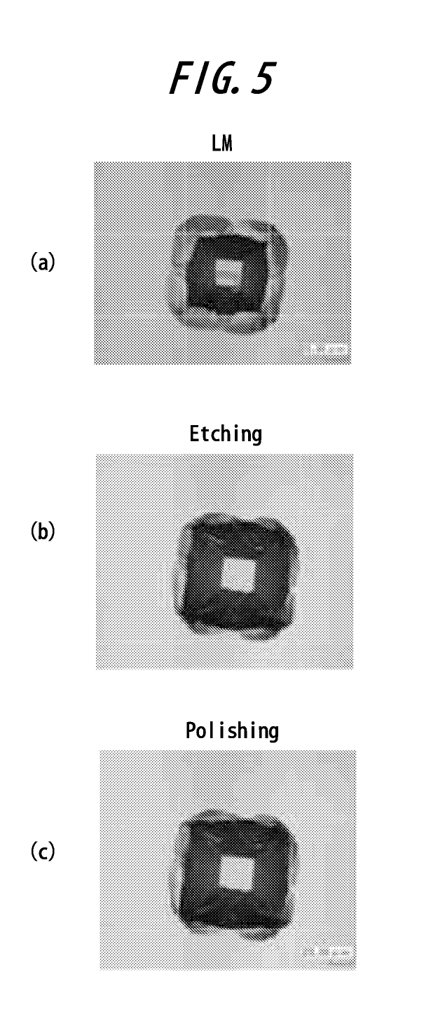

FIGS. 5 (a) to (c) show results on the state of the laser mark observed by the optical microscope in the semiconductor wafer of Reference Example during the production process, respectively, wherein (a) shows a state of the laser mark after the end of the laser mark printing step (step 3), and (b) shows a state of the laser mark after the end of the etching step (step 5), and (c) shows a state of the laser mark after the end of the polishing step with no abrasive grain (step 6). As seen from the results of FIGS. 5 (a) to (c), uneven elevated portions observed in the periphery of the laser mark-printed site after the end of the laser mark printing step are not etched completely after the end of the etching step, the state of which is maintained even after the end of the polishing step with no abrasive grain, so that the uneven elevated portions remain without removal. Also, the flatness of the finally obtained semiconductor wafer is more than 1 μm, which has been deteriorated.

According to the method for producing a laser-marked semiconductor wafer according to the invention, even if polishing with a polishing solution containing no abrasive grain is conducted in the polishing step, influences based on the minute and uneven elevated portions formed in the periphery of the print site by the laser marking, welding of Si splattered particles generated during the printing and the like can be eradicated to prevent the deterioration of flatness in the vicinity of the print sites.

What is claimed is:

1. A method for producing a laser-marked semiconductor wafer which comprises a slicing step of cutting out a disc-shaped wafer from a single crystal ingot; a planarization step of making a thickness of the cut disc-shaped wafer uniform; a laser mark printing step of printing laser marks for wafer identification on the surface of the wafer through laser; a grinding step of grinding at least the laser-marked surface of the laser-marked wafer by a predetermined thickness considering (1) the removal of uneven elevated portions formed in the periphery of the laser mark-printed site and (2) the preservation of a depth of the laser mark-printed site; an etching step of etching at least the laser mark-printed sites of the wafer after the grinding; and a polishing step of polishing the wafer surface after the etching with a polishing solution containing no abrasive grain.

2. A method for producing a laser-marked semiconductor wafer according to claim 1, wherein the predetermined thickness to be ground in the grinding step is 5 to 50 μm.

3. A method for producing a laser-marked semiconductor wafer according to claim 1, wherein the planarization step is conducted by lapping both surfaces of the cut wafer.

4. A method for producing a laser-marked semiconductor wafer according to claim 1, wherein the laser marks printed in the laser mark printing step are formed on the surface of the wafer in the vicinity of a notch.

5. A method for producing a laser-marked semiconductor wafer according to claim 1, wherein the etching step is conducted with an alkaline solution.

6. A method for producing a laser-marked semiconductor wafer according to claim 1, wherein the polishing step comprises a double-sided first polishing step of simultaneously first-polishing both surfaces of the wafer with a polishing solution containing no abrasive grain and a one-side finish polishing step of finish-polishing at least one surface of both the first-polished surfaces of the wafer, one surface at a time, with a polishing solution containing no abrasive grain.
